(19) United States
(12) Patent Application Publication
(10) Pub. No.: US 2026/0150437 A1
(43) Pub. Date: May 28, 2026

(54) LIGHT EMITTING DIODE

(71) Applicant: QUANZHOU SANAN SEMICONDUCTOR TECHNOLOGY CO., LTD., Quanzhou (CN)

(72) Inventors: Min HUANG, Quanzhou (CN); Ruiqing LIANG, Quanzhou (CN); Yu-tsai TENG, Quanzhou (CN); Yaowei CHUANG, Quanzhou (CN); Chiahao TSAI, Quanzhou (CN); Mingxin CHEN, Quanzhou (CN); Jinwen CHEN, Quanzhou (CN)

(21) Appl. No.: 19/403,064

(22) Filed: Nov. 27, 2025

(30) Foreign Application Priority Data
Nov. 27, 2024 (CN) 202411718015.1
Mar. 11, 2025 (CN) 202510286167.7

(51) Int. Cl. H10H 20/831; H10H 20/82

(52) U.S. Cl. CPC H10H 20/8314; H10H 20/82

(57) ABSTRACT

A light emitting diode includes: a substrate, including first and second surfaces, and a side surface connecting the first and second surfaces; a semiconductor stack, disposed on a first surface of the substrate, the semiconductor stack includes: a first semiconductor layer, an active layer, and a second semiconductor layer; and first and second electrodes. The side surface includes a first side surface and a second side surface; and the first side surface includes at least one first cutting mark, the second side surface includes at least one second cutting mark, a spacing between one first cutting mark near the first surface and the first surface is a first spacing S1, a spacing between one second cutting mark near the first surface and the first surface is a second spacing S2, and the first spacing S1 is not equal to the second spacing S2.

### CROSS-REFERENCE TO RELATED APPLICATIONS

This application claims the priority of Chinese Patent Application No. 202510286167.7, filed on Mar. 11, 2025, and the priority of Chinese Patent Application No. 202411718015.1, filed on Nov. 27, 2024, both of which are herein incorporated by reference in their entireties.

### TECHNICAL FIELD

The present disclosure relates to the field of semiconductor manufacturing technologies, and particularly to a light emitting diode (LED) and a light emitting device.

### BACKGROUND

LEDs are used in various products such as large backlight units (BLUs), general lighting, and electronic devices, and are also used in various small household appliances and interior decoration products. Furthermore, the LEDs are not only simply used as light sources but also for various purposes such as conveying information and evoking aesthetic sensations.

### SUMMARY

In an embodiment, the present disclosure provides an LED, which includes: a substrate, the substrates includes a first surface, a second surface, and a side surface connecting the first surface and the second surface; a semiconductor stack, disposed on the first surface of the substrate, the semiconductor stack includes a first semiconductor layer, an active layer, and a second semiconductor layer stacked sequentially in that order; a first electrode, disposed on the semiconductor stack and electrically connected to the first semiconductor layer; and a second electrode, disposed on the semiconductor stack and electrically connected to the second semiconductor layer. The side surface includes a first side surface and a second side surface connected to the first side surface. The first side surface is adjacent to the first electrode or the second electrode. The second side surface is adjacent to the first electrode and the second electrode. The first side surface includes at least one first cutting mark, and the second side surface includes at least one second cutting mark. A spacing between one of the at least one first cutting mark near the first surface of the substrate and the first surface of the substrate is a first spacing S1, and a spacing between one of the at least one second cutting mark near the first surface of the substrate and the first surface of the substrate is a second spacing S2. The first spacing S1 is not equal to the second spacing S2.

In an embodiment, the present disclosure provides another LED, which includes: a substrate, the substrate includes a first surface, a second surface, and a side surface connecting the first surface and the second surface; a semiconductor stack, disposed on the first surface of the substrate, the semiconductor stack includes a first semiconductor layer, an active layer, and a second semiconductor layer stacked sequentially in that order; a first electrode, disposed on the semiconductor stack and electrically connected to the first semiconductor layer; and a second electrode, disposed on the semiconductor stack and electrically connected to the second semiconductor layer. The side surface includes a first side surface and a second side surface connected to the first side surface. The first side surface is adjacent to the first electrode or the second electrode. The second side surface is adjacent to the first electrode and the second electrode. The first side surface includes a first cutting mark, and the second side surface includes a second cutting mark. The first cutting mark includes first laser-induced burst points. The second cutting mark includes second laser-induced burst points. A spacing between adjacent two first laser-induced burst points of the first laser-induced burst points is a first spacing D1. A spacing between adjacent two second laser-induced burst points of the second laser-induced burst points is a second spacing D2. The first spacing D1 is greater than the second spacing D2.

In an embodiment, the present disclosure provides yet another LED, which includes: a substrate, the substrate includes a first surface, a second surface, and a side surface connecting the first surface and the second surface; a semiconductor stack, disposed on the first surface of the substrate, the semiconductor stack includes a first semiconductor layer, an active layer, and a second semiconductor layer stacked sequentially in that order; a first electrode, disposed on the semiconductor stack and electrically connected to the first semiconductor layer; and a second electrode, disposed on the semiconductor stack and electrically connected to the second semiconductor layer. The substrate includes a first step. The first step includes a side wall and a mesa connected to the side wall, the side wall is connected to the first surface of the substrate, and the mesa is connected to the side surface of the substrate.

### BRIEF DESCRIPTION OF DRAWINGS

In order to more clearly illustrate the technical solutions in embodiments of the present disclosure or the related art, the following will briefly introduce accompanying drawings needed for describing the embodiments or the related art. Apparently, the accompanying drawings in the following description are some embodiments of the present disclosure. For those of ordinary skill in the art, other drawings can be obtained based on these accompanying drawings without creative effort; the positional relationships described in the accompanying drawings below, unless otherwise specified, are based on the direction in which the components are drawn in the accompanying drawings.

FIG. 1 illustrates a schematic plan view of an LED according to an embodiment of the present disclosure.

FIG. 2 illustrates a schematic cross-sectional view taken along a line A-A′ in FIG. 1.

FIG. 3 illustrates a schematic plan view of the LED of FIG. 1 with some structural layers omitted.

FIG. 4 illustrates a schematic view of a first side surface M1 of the LED.

FIG. 5 illustrates a schematic view of a second side surface M2 of the LED.

FIG. 6 illustrates an enlarged schematic view of a region A in FIG. 4.

### DETAILED DESCRIPTION OF EMBODIMENTS

In order to make objectives, technical solutions, and advantages of the embodiments of the present disclosure clearer, the following will clearly and completely describe the technical solutions in the embodiments of the present disclosure in conjunction with the accompanying drawings. Apparently, the described embodiments are part of embodiments of the present disclosure, not all of them. The technical features described in different implementations of the present disclosure below can be combined with each other as long as they do not conflict with each other. Based on the described embodiments of the present disclosure, all other embodiments obtained by a person of ordinary skill in the art without creative effort shall fall within the scope of protection of the present disclosure.

Same reference numerals and/or labels may be reused in different embodiments disclosed below. This repetition is for the purpose of simplification and clarity and does not indicate a specific relationship between the discussed different embodiments and/or structures.

An LED according to an embodiment of the present disclosure may be a flip-chip LED. The flip-chip LED may be a conventional size LED, for example, with a size in a range of 90000 μm² to 2000000 μm². The flip-chip LED may also be a small-size or micro-size flip-chip LED, for example, a micro-LED with a size within 90000 μm², having a length and/or width of 100 μm to 500 μm, and a height of 40 μm to 200 μm. The flip-chip LED may also be a micro-LED with an even smaller size, for example, having a length from 2 μm to 100 μm, a width from 2 μm to 100 μm, and a height from 2 μm to 100 μm.

The present disclosure uses a flip-chip LED as an example for illustration, but a lateral LED also conforms to a design concept of the present disclosure.

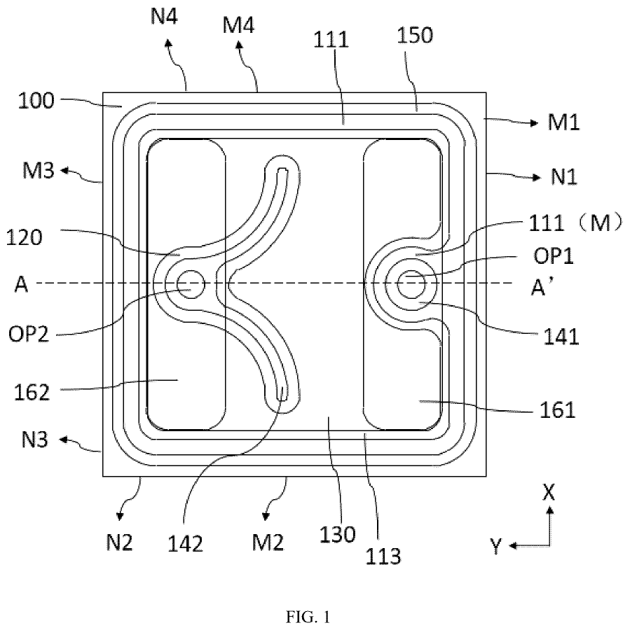

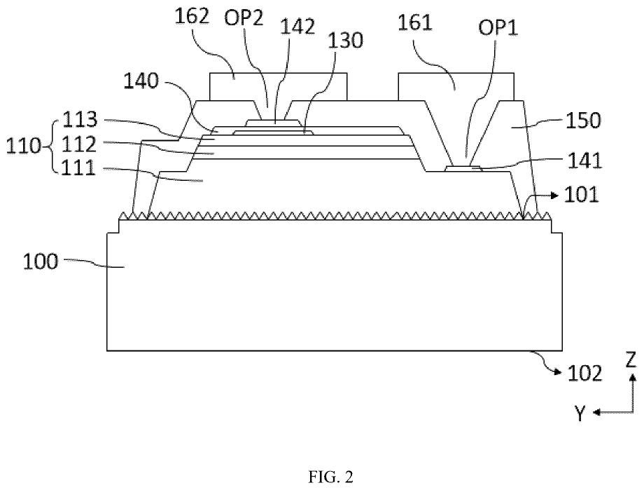

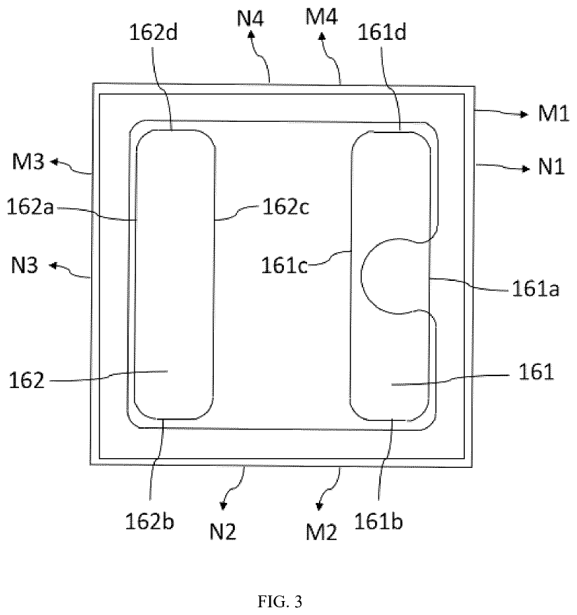

FIG. 1 illustrates a schematic plan view of an LED according to an embodiment of the present disclosure, FIG. 2 illustrates a schematic cross-sectional view taken along a line A-A′ in FIG. 1, and FIG. 3 illustrates a schematic plan view of the LED of FIG. 1 with some structural layers omitted.

As shown in FIG. 1 and FIG. 2, the LED of this embodiment includes a substrate 100, a semiconductor stack 110, a current blocking layer 120, a transparent conductive layer 130, a first contact electrode 141, a second contact electrode 142, an insulating layer 150, a first electrode 161, and a second electrode 162.

The substrate 100 may be an insulating substrate or a conductive substrate. The substrate 100 may be a growth substrate for growing the semiconductor stack 110, and may include a sapphire substrate, a silicon carbide substrate, a silicon substrate, a gallium nitride substrate, or an aluminum nitride substrate. Additionally, the substrate 100 may include protrusions formed on at least a portion of an upper surface of the substrate 100. The protrusions of the substrate 100 may be formed in a regular or irregular pattern. For example, the substrate 100 may be a patterned sapphire substrate (PSS) including protrusions formed on the upper surface thereof. The substrate 100 may have a thickness in a range of approximately 100 μm to 200 μm.

As shown in FIG. 1, the substrate 100 has a first edge N1, a second edge N2, a third edge N3, and a fourth edge N4 connected sequentially in that order. An edge of the substrate 100 may be equivalent to an edge of the LED. The first edge N1 and the third edge N3 extend along a first direction X, and the second edge N2 and the fourth edge N4 extend along a second direction Y. A thickness direction of the substrate 100 is a third direction Z. The substrate 100 includes a first surface 101, a second surface 102 opposite the first surface 101, and a side surface connecting the first surface 101 and the second surface 102. This side surface includes a first side surface M1, a second side surface M2, a third side surface M3, and a fourth side surface M4 connected sequentially in that order. The fourth side surface M4 is connected to the first side surface M1. The first side surface M1 and the third side surface M3 are opposite each other, and the second side surface M2 and the fourth side surface M4 are opposite each other. The first surface 101 specifically includes the first edge N1 connected to the first side surface M1, the second edge N2 connected to the second side surface M2, the third edge N3 connected to the third side surface M3, and a fourth edge N4 connected to the fourth side surface M4. The first edge N1, the second edge N2, the third edge N3, and the fourth edge N4 are connected sequentially in that order.

As shown in FIG. 1 and FIG. 2, the semiconductor stack 110 is disposed on the first surface 101 of the substrate 100. Additionally, an area of a lower surface of the semiconductor stack 110 may be smaller than an area of the first surface 101 of the substrate 100, exposing a portion of the first surface 101 of the substrate 100 along an outer edge of the semiconductor stack 110. The first surface 101 of the substrate 100 includes a portion covered by the semiconductor stack 110 and a portion not covered by the semiconductor stack 110. A portion of protrusions on the first surface 101 of the substrate 100 are disposed between the semiconductor stack 110 and the substrate 100, and a portion of the protrusions not covered by the semiconductor stack 110 are exposed around a periphery of the semiconductor stack 110.

As shown in FIG. 1 and FIG. 2, the semiconductor stack 110 includes a first semiconductor layer 111, a second semiconductor layer 113 disposed on the first semiconductor layer 111, and an active layer 112 disposed between the first semiconductor layer 111 and the second semiconductor layer 113, stacked sequentially in that order in the third direction Z of the substrate 100. An overall thickness of the semiconductor stack 110 may be in a range of approximately 3 μm to 10 μm.

The first semiconductor layer 111, the active layer 112, and the second semiconductor layer 113 may include a III-V group nitride-based semiconductor, for example, a nitride-based semiconductor such as (Al, Ga, In)N. The first semiconductor layer 111 may include an n-type impurity (e.g., Si, Ge, or Sn), and the second semiconductor layer 113 may include a p-type impurity (e.g., Mg, Sr, or Ba). Alternatively, the first semiconductor layer 111 may include a p-type impurity (e.g., Mg, Sr, or Ba), and the second semiconductor layer 113 may include an n-type impurity (e.g., Si, Ge, or Sn). The active layer 112 may include a multi-quantum well structure (MQW), and a composition ratio of the nitride-based semiconductor can be adjusted to emit a desired wavelength. Particularly, in this embodiment, the second semiconductor layer 113 may be a p-type semiconductor layer.

The semiconductor stack 110 includes a local defect region M exposing a partial surface of the first semiconductor layer 111. Specifically, the semiconductor stack 110 may be formed by removing the second semiconductor layer 113, the active layer 112, and a portion of the first semiconductor layer 111 through processes such as etching, thereby forming the local defect region M that exposes the partial surface of the first semiconductor layer 111. The local defect region M may be located outside the second semiconductor layer 113 and surround the second semiconductor layer 113. In another embodiment, the local defect region M (a through-hole or through-groove) may also be formed inside the semiconductor stack 110 to expose the partial surface of the first semiconductor layer 111.

As shown in FIG. 1 and FIG. 2, the transparent conductive layer 130 is disposed on the second semiconductor layer 113. The transparent conductive layer 130 may be in ohmic contact with the second semiconductor layer 113. The transparent conductive layer 130 may include, for example, a transparent conductive oxide layer such as Indium Tin Oxide (ITO), Zinc Oxide (ZnO), Zinc Indium Tin Oxide (ZITO), Zinc Indium Oxide (ZIO), Zinc Tin Oxide (ZTO), Gallium Indium Tin Oxide (GITO), Gallium Indium Oxide (GIO), Gallium Zinc Oxide (GZO), Aluminum doped Zinc Oxide (AZO), or Fluorine Tin Oxide (FTO). The conductive oxide may also include various dopants.

In this embodiment, a thickness of the transparent conductive layer 130 is between 50 nm and 200 nm. If a size of the LED is less than 300 μm ×150 μm, and a thickness of the transparent conductive layer 130 is less than 50 nm, a current may not spread well, leading to poor (electro-static discharge) ESD capability of the LED. If the thickness of the transparent conductive layer 130 is greater than 200 nm, the transparent conductive layer 130 may absorb light and cause losses.

The first contact electrode 141 is disposed on the first semiconductor layer 111, specifically, the first contact electrode 141 is disposed on the local defect region M. The first contact electrode 141 is in ohmic contact with the first semiconductor layer 111 and is configured to disperse current. For this purpose, the first contact electrode 141 includes a metal layer, which is in ohmic contact with the first semiconductor layer 111.

In an embodiment, the first contact electrode 141 may be formed in a block shape in the local defect region M.

The first contact electrode 141 does not overlap with the active layer 112 or the second semiconductor layer 113, thereby omitting an insulating layer for insulating the first contact electrode 141 from the second semiconductor layer 113. The first contact electrode 141 can be formed, for example, using a lift-off process on the semiconductor stack 110 on which the transparent conductive layer 130 is disposed. Further, the first contact electrode 141 may be formed together with the second contact electrode 142 described below.

The second contact electrode 142 is disposed on the transparent conductive layer 130 and electrically connected to the transparent conductive layer 130, thereby aiding current dispersion within the second semiconductor layer 113.

The second contact electrode 142 may include a connection portion and an extension portion extending from the connection portion.

To reduce light absorption caused by the second contact electrode 142, the second contact electrode 142 is restrictively formed on a portion of an area of the transparent conductive layer 130. A total area of the second contact electrode 142 does not exceed 2/10 of an area of the transparent conductive layer 130. The second contact electrode 142 may include a starting portion and an extension portion.

The first contact electrode 141 and the second contact electrode 142 may be formed simultaneously in a same process using a same material, and thus may have a same layer structure. For example, the first contact electrode 141 and the second contact electrode 142 may include an Al reflection layer, which may include Au. Specifically, the first contact electrode 141 and the second contact electrode 142 may have a layer structure of Cr/Al/Ti/Ni/Ti/Ni/Au/Ti. In another embodiment, to reduce cost, the first contact electrode 141 and the second contact electrode 142 may also not include Au.

As shown in FIG. 1 and FIG. 2, to also prevent current concentration at the second semiconductor layer 113 below the second contact electrode 142, the current blocking layer 120 is provided between the second semiconductor layer 113 and the transparent conductive layer 130. This current blocking layer 120 is an insulating material layer, such as an SiO₂ and/or SiN material layer.

The insulating layer 150 is disposed on the semiconductor stack 110. Specifically, the insulating layer 150 may cover the semiconductor stack 110, the transparent conductive layer 130, the first contact electrode 141, and the second contact electrode 142. The insulating layer 150 defines a first opening OP1 and a second opening OP2. The first opening OP1 exposes a portion of a surface of the first contact electrode 141, and the second opening OP2 exposes a portion of a surface of the second contact electrode 142. A size of the first opening OP1 is smaller than an area of the first contact electrode 141, and a size of the second opening OP2 is smaller than an area of the second contact electrode 142.

The insulating layer 150 includes a distributed Bragg reflector. The distributed Bragg reflector may be formed by repeatedly stacking dielectric layers with different refractive indices. The dielectric layers may include at least one of TiO₂, SiO₂, HfO₂, ZrO₂, Nb₂O₅, or MgF₂. For example, the insulating layer 150 may have a structure of alternately stacked TiO₂ layers and SiO₂ layers. The distributed Bragg reflector is designed to reflect light generated in the active layer 112 and a total of the distributed Bragg reflector is multiple pairs to improve reflectivity. In this embodiment, the distributed Bragg reflector may include 10 to 25 pairs. The insulating layer 150 may include, together with the distributed Bragg reflector, additional insulating layers. For example, to improve adhesion between the distributed Bragg reflector and its underlying layer, a dielectric layer located below the distributed Bragg reflector and a protective layer covering the distributed Bragg reflector may be included. The dielectric layer may be formed, for example, by an SiO₂ layer, and the protective layer may be formed by SiNₓ. A layer formed of SiNₓ has excellent moisture resistance, thereby protecting the LED from moisture.

The insulating layer 150 may have a thickness of about 2 μm to 5 μm. A reflectivity of the distributed Bragg reflector for light generated in the active layer 112 may be 90% or more, and by controlling types, thicknesses, or stacking periods of the multiple dielectric layers forming the distributed Bragg reflector, a reflectivity close to 100% can be achieved. Furthermore, the distributed Bragg reflector may also have high reflectivity for other visible light besides the light generated in the active layer 112.

The first electrode 161 and the second electrode 162 are disposed on the insulating layer 150. The first electrode 161 penetrates through the first opening OP1 and is in contact with the first contact electrode 141, thereby being electrically connected to the first semiconductor layer 111. The second electrode 162 penetrates through the second opening OP2 and is in contact with the second contact electrode 142, thereby being electrically connected to the second semiconductor layer 113.

The first electrode 161 and the second electrode 162 may be formed simultaneously in a same process using a same material, and thus may have a same layer structure. A thickness of each of the first electrode 161 and the second electrode 162 may be thinner than a thickness of the insulating layer 150, for example, the thickness of each of the first electrode 161 and the second electrode 162 may be about 2 μm. Alternatively, the thickness of each of the first electrode 161 and the second electrode 162 may also be thicker than the thickness of the insulating layer 150.

As shown in FIG. 3, the first electrode 161 includes a first edge 161a adjacent to the first edge N1 of the substrate 100, a second edge 161b adjacent to the second edge N2 of the substrate 100, a third edge 161c adjacent to the second electrode 162, and a fourth edge 161d adjacent to the fourth edge N4 of the substrate 100.

The second electrode 162 includes a first edge 162a adjacent to the third edge N3 of the substrate 100, a second edge 162b adjacent to the second edge N2 of the substrate 100, a third edge 162c adjacent to the first electrode 161, and a fourth edge 162d adjacent to the fourth edge N4 of the substrate 100.

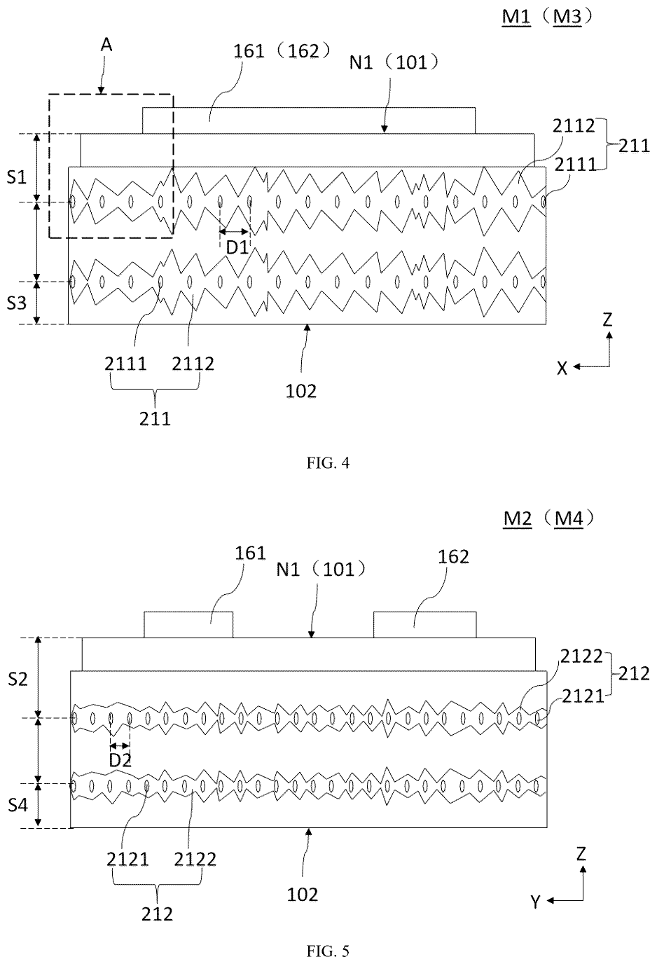

As shown in FIG. 4 and FIG. 5, FIG. 4 illustrates a schematic view of the first side surface M1, and FIG. 5 illustrates a schematic view of the second side surface M2. The first side surface M1 is adjacent to the first edge 161a of the first electrode 161. The second side surface M2 is adjacent to the second edge 161b of the first electrode 161 and the second edge 162b of the second electrode 162. The first side surface M1 has at least one first cutting mark 211 extending along the first direction X. The second side surface M2 has at least one second cutting mark 212 extending along the second direction Y. Similarly, the third side surface M3 is adjacent to the first edge 162a of the second electrode 162, and the fourth side surface M4 is adjacent to the fourth edge 161d of the first electrode 161 and the fourth edge 162d of the second electrode 162. The third side surface M3 has at least one first cutting mark 211 extending along the first direction X. The fourth side surface M4 has at least one second cutting mark 212 extending along the second direction Y.

In another embodiment (not shown in drawings), the third side surface M3 is adjacent to the first edge 161a of the first electrode 161, and the fourth side surface M4 is adjacent to the second edge 161b of the first electrode 161 and the second edge 162b of the second electrode 162. The third side surface M3 has at least one first cutting mark 211 extending along the first direction X. The fourth side surface M4 has at least one second cutting mark 212 extending along the second direction Y. Similarly, the first side surface M1 is adjacent to the first edge 162a of the second electrode 162, and the second side surface M2 is adjacent to the fourth edge 161d of the first electrode 161 and the fourth edge 162d of the second electrode 162. The first side surface M1 has at least one first cutting mark 211 extending along the first direction X. The second side surface M2 has at least one second cutting mark 212 extending along the second direction Y.

As shown in FIG. 4, the first cutting mark 211 includes first laser-induced burst points 2111 and a first etch texture 2112 (structurally altered zone) connected to the first laser-induced burst points 2111. The first etch texture 2112 is an irregularly distributed texture. In an embodiment, the first laser-induced burst points 2111 are arranged at substantially equal intervals, and a spacing between adjacent two first laser-induced burst points 2111 is a first spacing D1. A spacing between the first cutting mark 211 near the first surface 101 of the substrate 100 and the first surface 101 of the substrate 100 is a first spacing S1. As shown in FIG. 5, The second cutting mark 212 includes second laser-induced burst points 2121 and a second etch texture 2122 (structurally altered zone) connected to the second laser-induced burst points 2121. The second etch texture 2122 is an irregularly distributed texture. In an embodiment, the second laser-induced burst points 2121 are arranged at substantially equal intervals, and a spacing between adjacent two second laser-induced burst points 2121 is a second spacing D2. A spacing between the second cutting mark 212 near the first surface 101 of the substrate 100 and the first surface 101 of the substrate 100 is a second spacing S2. The first spacing S1 and the second spacing S2 are measured from one laser-induced burst point as a starting position to the first surface 101.

LEDs are typically singulated into individual chips using laser stealth dicing. This involves directing laser laser-induced burst points into an interior of the substrate 100 and causing internal burning and cracking; finally, adjacent chips are separated by a physical action of an external force from a breaking tool. However, this method may cause chipping at edges and corners of the chips, and the cracks from chipping may extend from the edges into the interior of the chips, causing hidden cracks in the semiconductor stacks of the LEDs, ultimately leading to dimming or micro-leakage in the LEDs.

In an embodiment, the first spacing S1 is not equal to the second spacing S2. By offsetting the positions of the first cutting mark 211 and the second cutting mark 212, the occurrence of a zigzag pattern structure at corners of the LED (i.e., corners of the substrate 100) can be avoided, improving an abnormal appearance of chipping and enhancing a straightness of the corners of the substrate.

In an embodiment, the first spacing S1 is less than the second spacing S2.

Since the first side surface M1 is adjacent to the first edge 161a of the first electrode 161 or the first edge 162a of the second electrode 162, if an energy of the stealth dicing laser laser-induced burst points is too high, it may damage the first edge 161a of the first electrode 161 or the first edge 162a of the second electrode 162, thereby affecting the reliability of the LED. Since the second side surface M2 is adjacent to the second edge 161b of the first electrode 161 and the second edge 162b of the second electrode 162 and there is a spacing between the first electrode 161 and the second electrode 162, the possibility of damage to the first electrode 161 and the second electrode 162 from the energy of the stealth dicing laser laser-induced burst points is relatively small. Therefore, the energy of the stealth dicing laser laser-induced burst points on the first side surface M1 should be smaller than that on the second side surface M2. Thus, the first spacing D1 between every adjacent two first laser-induced burst points 2111 of the first cutting mark 211 of the first side surface M1 is greater than the second spacing D2 between every adjacent two second laser-induced burst points 2121 of the second cutting mark 212 of the second side surface M2.

In an embodiment, the first spacing D1 is greater than or equal to 6 μm and less than or equal to 25 μm.

In an embodiment, the second spacing D2 is greater than or equal to 2 μm and less than or equal to 15 μm.

Since the first spacing D1 is greater than the second spacing D2, the first spacing S1 needs to be less than the second spacing S2, so that the first cutting mark 211 is closer to the semiconductor stack 110 of the LED compared with the second cutting mark 212. Otherwise, a fewer number of laser laser-induced burst points per unit area on the first side surface M1 results in insufficient laser energy, causing the semiconductor stack 110 of the LED not to crack completely, leading to chip chipping.

In an embodiment, the first spacing S1 is 8 μm or more, more preferably 8 μm to 45 μm. If this spacing is too low, on one hand, the laser is prone to damage an epitaxial layer during an etching process of the substrate 100; on the other hand, cracks generated during a dicing process may exceed the first spacing S1 from the first surface 101 of the substrate 100 and reach the semiconductor stack 110, the insulating layer 150, or the electrodes 141 and 142. If the spacing is too large, the dicing process is prone to cause oblique cracking along a crystal lattice direction.

In an embodiment, the second spacing S2 is 20 μm or more, ensuring that the laser etching inside the substrate 100 does not damage the epitaxial layer, for example, it can be 20 μm to 60 μm.

In another embodiment (not shown), a thickness of the substrate 100 is h, the first spacing S1 is in a range of ⅓h to ⅔h, and the second spacing S2 is in a range of ⅓h to ⅔h.

In an embodiment, as shown in FIG. 4 and FIG. 5, the first side surface M1 has two first cutting marks 211, and the second side surface M2 has two second cutting marks 212. The spacing between the first cutting mark 211 near the second surface 102 of the substrate 100 and the second surface 102 of the substrate 100 is a third spacing S3. The spacing between the second cutting mark 212 near the second surface 102 of the substrate 100 and the second surface 102 of the substrate 100 is a fourth spacing S4. Similarly, each of the third spacing S3 and the fourth spacing S4 is measured from one laser-induced burst points as a starting position to the second surface 102.

In an embodiment, the third spacing S3 is greater than the fourth spacing S4.

In an embodiment, the first spacing S1 is less than the third spacing S3, and the second spacing S2 is less than the fourth spacing S4.

In an embodiment, a spacing between the two first cutting marks 211 on the first side surface M1 is less than a spacing between the two second cutting marks 212 on the second side surface M2. A spacing between adjacent two first cutting marks 211 may be 10 μm to 50 μm. A spacing between adjacent two second cutting marks 212 may be 10 μm to 50 μm.

In the process of singulating chips using laser stealth dicing, on one hand, insufficient laser energy may cause the semiconductor stack on an electrode side of the LED not to crack completely, leading to chip chipping; on the other hand, the etch textures formed by the release of thermal stress from the stealth laser laser-induced burst points may extend from the edge into the interior of the chip, causing hidden cracks in the semiconductor stack of the LED, leading to dimming or micro-leakage of the LED.

Therefore, in an embodiment, a first step 200 may first be formed from the first surface 101 of the substrate 100 downward by burning and cracking using a laser or other methods along a chip singulation dicing line; then, chip singulation is performed using laser stealth dicing and the physical action of external force from a breaking tool. This can avoid chip chipping caused by insufficient laser energy preventing the complete cracking of the semiconductor stack on the electrode side of the LED.

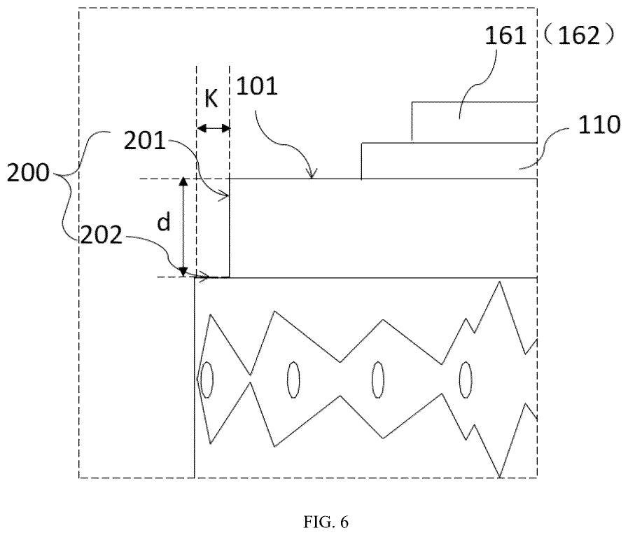

FIG. 6 illustrates a schematic enlarged schematic view of a region A in FIG. 4.

As shown in FIG. 6, the substrate 100 includes a first step 200. The first step 200 includes a side wall 201 and a mesa 202 connected to the side wall 201. The side wall 201 is connected to the first surface 101 of the substrate 100, and the mesa 202 is connected to the side surfaces (first side surface M1, second side surface M2, third side surface M3, and fourth side surface M4) of the substrate 100. After the first step 200 is formed by processing the first surface 101 of the substrate 100, a spacing between the mesa 202 and the stealth dicing laser-induced burst point 2111 or 2121 is shorter relative to the first surface 101 of the substrate 100, making stress release easier. Therefore, during the release of thermal stress from the stealth laser laser-induced burst points, a direction of cracking will extend to the position of the first step 200 and will not damage the interior of the chip, thereby fundamentally improving the phenomenon of chipping and ensuring that micro-cracks at the edge of the substrate 100 do not propagate into the chip interior, thus reducing the risk of leakage under low current and improving brightness under low current.

In an embodiment, a spacing between the first etch texture 2112 of the first cutting mark 211 and the mesa 201 of the first step 200 is less than a spacing between the second etch texture 2122 of the second cutting mark 212 and the mesa 201 of the first step 200.

The side wall 201 between the first step 200 and the first surface 101 becomes a rough surface with a cross-hatched pattern due to laser burning and cracking.

In an embodiment, a depth d of the side wall 201 in the third direction Z is in a range of 2μm to 20 μm. If the depth d is less than 2 μm, the first step 200 cannot improve chip chipping and leakage risk; if the depth d is greater than 20 μm, the laser energy required to form the first step 200 may be too high and damage the epitaxial layer. In an embodiment, a width K of the mesa 202 in the first direction X or the second direction Y is in a range of 0.1 μm to 2 μm. If the width K is less than 0.1 μm, it cannot block the extension of thermal stress from the stealth laser laser-induced burst points towards the semiconductor stack 110, the insulating layer 150, or the electrodes 161 and 162; if the width K is greater than 2 μm, the laser energy required to form the first step 200 may be too high and damage the epitaxial layer.

In an embodiment, a thickness of the substrate 100 is in a range of 60 μm to 200 μm.

In an embodiment, the thickness of the substrate 100 is h, the first spacing S1 is less than ⅓h, and the second spacing S2 is less than ⅓h. Since the first step 200 is formed by processing the first surface 101 of the substrate 100, during the release of thermal stress from the stealth laser laser-induced burst points, the direction of cracking will extend to the position of the first step 200 and will not damage the interior of the chip. Therefore, having the first spacing S1 and the second spacing S2 less than ⅓h can both avoid chip chipping caused by insufficient laser energy preventing the complete cracking of the semiconductor stack on the electrode side and prevent damage to the chip interior during the release of thermal stress from the stealth laser laser-induced burst points.

What is claimed is:

1. A light emitting diode (LED), comprising:
a substrate, comprising: a first surface, a second surface, and a side surface connecting the first surface and the second surface;
a semiconductor stack, disposed on a first surface of the substrate, wherein the semiconductor stack comprises: a first semiconductor layer, an active layer, and a second semiconductor layer stacked sequentially in that order;
a first electrode, disposed on the semiconductor stack and electrically connected to the first semiconductor layer;
a second electrode, disposed on the semiconductor stack and electrically connected to the second semiconductor layer;
wherein the side surface comprises a first side surface and a second side surface connected to the first side surface, the first side surface is adjacent to the first electrode or the second electrode, the second side surface is adjacent to the first electrode and the second electrode; and the first side surface comprises at least one first cutting mark, the second side surface comprises at least one second cutting mark, a spacing between one of the at least one first cutting mark near the first surface of the substrate and the first surface of the substrate is a first spacing S1, a spacing between one of the at least one second cutting mark near the first surface of the substrate and the first surface of the substrate is a second spacing S2, and the first spacing S1 is not equal to the second spacing S2.

2. The LED as claimed in claim 1, wherein the first spacing S1 is less than the second spacing S2.

3. The LED as claimed in claim 1, wherein the first spacing S1 is in a range of 8 μm to 45 μm, and the second spacing S2 is in a range of 20 μm to 60 μm.

4. The LED as claimed in claim 1, wherein the at least one first cutting mark is two in number, the at least one second cutting marks is two in number, and a spacing between the two first cutting marks on the first side surface is less than a spacing between the two second cutting marks on the second side surface.

5. The LED as claimed in claim 1, wherein a spacing between one of the at least one first cutting mark near the second surface of the substrate and the second surface of the substrate is a third spacing S3, a spacing between one of the at least one second cutting mark near the second surface of the substrate and the second surface of the substrate is a fourth spacing S4, and the third spacing S3 is greater than the fourth spacing S4.

6. The LED as claimed in claim 5, wherein the first spacing S1 is less than the third spacing S3, and the second spacing S2 is less than the fourth spacing S4.

7. The LED as claimed in claim 1, wherein a thickness of the substrate is h, the first spacing S1 is in a range of ⅓h to ⅔h, and the second spacing S2 is in a range of ⅓h to ⅔h.

8. The LED as claimed in claim 1, wherein each of the at least one first cutting mark comprises first burst points, each of the at least one second cutting mark comprises second burst points, a spacing between adjacent two first burst points of the first laser-induced burst points is a first spacing D1, a spacing between adjacent two second burst points of the second burst points is a second spacing D2, and the first spacing D1 is greater than the second spacing D2.

9. The LED as claimed in claim 8, wherein the first spacing D1 is in a range of 6 μm to 25 μm, and the second spacing D2 is in a range of 2 μm to 15 μm.

10. The LED as claimed in claim 1, wherein the substrate further comprises a first step, the first step comprises a side wall and a mesa connected to the side wall, the side wall is connected to the first surface of the substrate, and the mesa is connected to the side surface of the substrate.

11. The LED as claimed in claim 10, wherein a depth of the side wall is in a range of 2 μm to 20 μm, and a width of the mesa is in a range of 0.1 μm to 2 μm.

12. The LED as claimed in claim 10, wherein the first cutting mark comprises first burst points and a first etch texture connected to the first burst points, the second cutting mark comprises second burst points and a second etch texture connected to the second burst points, and a spacing between the first etch texture and the mesa of the first step is less than a spacing between the second etch texture and the mesa of the first step.
